(19) United States
(12) Patent Application Publication
(10) Pub. No.: US 2010/0284541 A1
(43) Pub. Date: Nov. 11, 2010

(54) RECEIVING APPARATUS

(75) Inventor: Masaaki Taira, Akashi-shi (JP)

Correspondence Address: OSHA LIANG L.L.P., TWO HOUSTON CENTER, 909 FANNIN, SUITE 3500, HOUSTON, TX, 77010, US

(73) Assignees: SANYO ELECTRIC CO., LTD., Osaka (JP); SANYO SEMICONDUCTOR CO., LTD., Ora-Gun (JP)

(21) Appl. No.: 12/773,066

(22) Filed: May 4, 2010

(30) Foreign Application Priority Data
May 7, 2009 (JP) 2009-112927

(51) Int. Cl. H03G 9/00; H04R 5/00

(52) U.S. Cl. 381/1; 381/102

(57) ABSTRACT

A receiving apparatus comprising: a frequency conversion unit configured to convert a received radio frequency signal to an intermediate frequency signal; an automatic gain control unit configured to control an amplitude level of at least either one of the radio frequency signal and the intermediate frequency signal according to a gain control signal; a demodulation unit configured to demodulate an audio signal from the intermediate frequency signal; a correction level output unit configured to output a correction level signal corresponding to a difference between a demodulation unit input level and a predetermined reference level, the demodulation unit input level being an amplitude level of the intermediate frequency signal inputted to the demodulation unit; and an addition unit configured to add the gain control signal and the correction level signal, to be outputted as a signal strength signal indicating received signal strength of the radio frequency signal.

### CROSS-REFERENCE TO RELATED APPLICATION

This application claims the benefit of priority to Japanese Patent Application No. 2009-112927, filed May 7, 2009, of which full contents are incorporated herein by reference.

### BACKGROUND OF THE INVENTION

1. Field of the Invention

The present invention relates to a receiving apparatus.

2. Description of the Related Art

In radio communication, a received signal is subjected to filtering processing, frequency conversion processing, amplification processing and the like, to be demodulated to a baseband signal in general. Also, a receiving apparatus is generally known, which detects a reception status such as signal strength of the received signal or presence/absence of an interference signal, and which controls characteristics such as the filtering processing and the amplification processing according to the reception status, in order to improve a communication quality in the radio communication.

For example, Japanese Patent Laid-Open Publication No. 2006-86685 discloses a receiving apparatus (AM car-radio receiver) including a signal strength determination means for determining received signal strength from an output control voltage of an AGC (Automatic Gain Control) circuit. In the receiving apparatus, strength of the received signal is determined by which is greater or smaller between the output control voltage of the AGC circuit and a predetermined reference value, to switch channel selection sensitivity of automatic channel selecting means according to such determination result.

As mentioned above, the received signal strength can be determined by the output control voltage of the AGC circuit, and moreover, optimal channel selection sensitivity can be set using the received signal strength, so that communication quality of the receiving apparatus can be improved.

In a common AGC circuit, a gain control signal for controlling a gain of an amplifier or an attenuation quantity (negative gain) of an attenuator is generated so that the higher an amplitude level of an output signal of the amplifier or the attenuator is, the smaller the gain becomes, and the lower the amplitude level of the output signal is, the greater the gain becomes.

Here, there is illustrated in FIG. 6 an example of a relationship between the amplitude level of the output signal and the gain control signal. FIG. 6 shows a case where an amplitude level L1 (short broken line) of the output signal is lowered once at the time of t=0 to become lower than a reference level Ref1 (dashed-dotted line). As illustrated in FIG. 6, a gain control signal G1 (solid line) is generated by smoothing a difference between the amplitude level L1 and the reference level Ref1, and the amplitude level L1 is gradually raised according to a smoothed gain control signal G1. Then, in FIG. 6, the gain control signal G1 becomes stable at the time of t=t1.

However, such an AGC circuit is required to be provided with a smoothing processing unit having a large time constant to such a degree that the gain control signal G1 is not oscillated. Thus, a response speed of the gain control signal G1 is limited by the time constant, and a longer time is required for the received signal strength, which can be determined by the gain control signal G1, to become stable.

### SUMMARY OF THE INVENTION

A receiving apparatus according to an aspect of the present invention, comprises: a frequency conversion unit configured to convert a received radio frequency signal to an intermediate frequency signal; an automatic gain control unit configured to control an amplitude level of at least either one of the radio frequency signal and the intermediate frequency signal according to a gain control signal; a demodulation unit configured to demodulate an audio signal from the intermediate frequency signal; a correction level output unit configured to output a correction level signal corresponding to a difference between a demodulation unit input level and a predetermined reference level, the demodulation unit input level being an amplitude level of the intermediate frequency signal inputted to the demodulation unit; and an addition unit configured to add the gain control signal and the correction level signal, to be outputted as a signal strength signal indicating received signal strength of the radio frequency signal.

Other features of the present invention will become apparent from descriptions of this specification and of the accompanying drawings.

### BRIEF DESCRIPTION OF THE DRAWINGS

For more thorough understanding of the present invention and advantages thereof, the following description should be read in conjunction with the accompanying drawings, in which:

FIG. 1 is a block diagram illustrating a configuration of a receiving apparatus including a signal strength detection unit according to a first embodiment of the present invention;

FIG. 2 is a schematic diagram illustrating an example of a relationship between an input signal and an output signal in a correction level output unit 202;

FIG. 3 is a schematic diagram illustrating an example of a relationship between an input signal and an output signal in an addition unit 203;

FIG. 4 is a block diagram illustrating a configuration of a receiving apparatus including a signal strength detection unit according to a second embodiment of the present invention;

FIG. 5 is a block diagram illustrating a configuration of a receiving apparatus including a signal strength detection unit according to a third embodiment of the present invention; and

FIG. 6 is a schematic diagram illustrating an example of a relationship between an amplitude level of an output signal of an amplifier or an attenuator in a common AGC circuit and a gain control signal.

### DETAILED DESCRIPTION OF THE INVENTION

At least the following details will become apparent from descriptions of this specification and of the accompanying drawings.

### First Embodiment

### Configuration of Receiving Apparatus

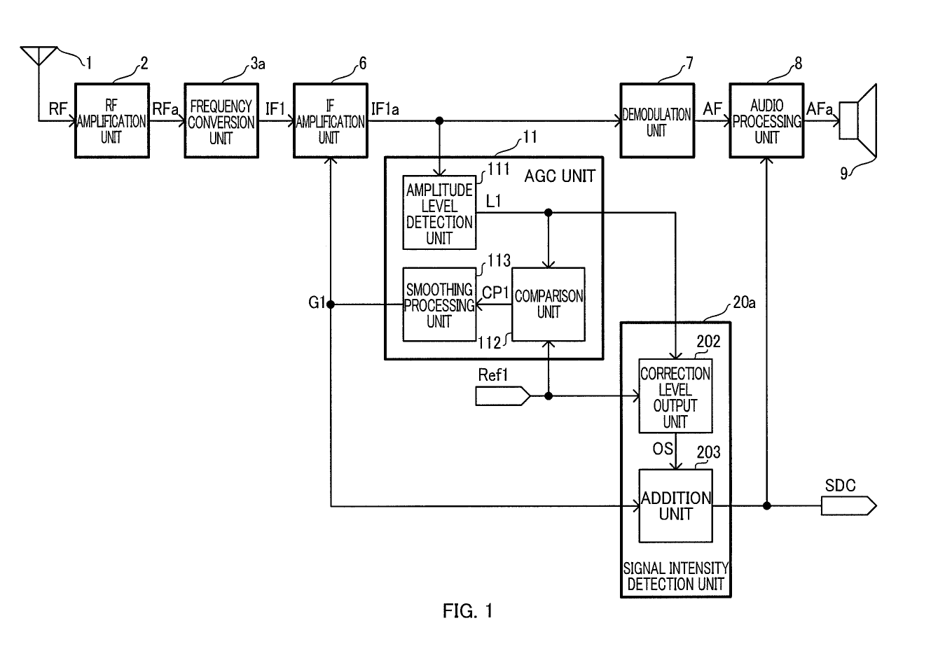

There will hereinafter be described a configuration of a receiving apparatus including a signal strength detection unit according to a first embodiment of the present invention, referring to FIG. 1.

The receiving apparatus illustrated in FIG. 1 includes an antenna 1, an RF (Radio Frequency) amplification unit 2, a frequency conversion unit 3a, IF (intermediate Frequency) amplification unit 6, a demodulation unit 7, an audio processing unit 8, a speaker 9, an AGC unit 11, and a signal strength detection unit 20a. The receiving apparatus is used for receiving FM radio broadcasting or AM radio broadcasting, for example.

An RF signal outputted from the antenna 1 is inputted to the RF amplification unit 2, and an RFa signal outputted from the RF amplification unit 2 is inputted to the frequency conversion unit 3a. An IF1 signal outputted from the frequency conversion unit 3a is inputted to the IF amplification unit 6, and an IF1a signal outputted from the IF amplification unit 6 is inputted to the demodulation unit 7. Moreover, an AF (Audio Frequency) signal outputted from the demodulation unit 7 is inputted to the audio processing unit 8, and an AFa signal outputted from the audio processing unit 8 is inputted to the speaker 9.

On the other hand, the IF1a signal is inputted to the AGC unit 11 as well. The AGC unit 11 includes an amplitude level detection unit 111, a comparison unit 112, and a smoothing processing unit 113, for example, and the IF1a signal is inputted to the amplitude level detection unit 111. An output level L1 of the amplitude level detection unit 111 and a reference level Ref1 are inputted to the comparison unit 112, and a comparison result signal CP1 outputted from the comparison unit 112 is inputted to the smoothing processing unit 113. And a gain control signal G1 outputted from the smoothing processing unit 113 is inputted to the IF amplification unit 6 and the signal strength detection unit 20a.

The signal strength detection unit 20a includes a correction level output unit 202 and an addition unit 203, for example. The output level L1 of the amplitude level detection unit 111 and the reference level Ref1 are inputted to the correction level output unit 202. A correction level signal OS outputted from the correction level output unit 202 and the gain control signal G1 are inputted to the addition unit 203. And then, a signal strength signal SDC outputted from the addition unit 203 is inputted to the audio processing unit 8, for example.

### ===Operation of Receiving Apparatus===

Subsequently, there will be described an operation of the receiving apparatus according to an embodiment of the present invention.

The antenna 1 receives a broadcast wave of the FM radio broadcasting or AM radio broadcasting, for example, to output an RF signal. The RF amplification unit 2 selectively amplifies a frequency band including a desired carrier wave in the RF signal, to be outputted as the RFa signal. The frequency conversion unit 3a frequency-converts the RFa signal, rejects an interference signal (interference signal) as appropriate, such as an image signal or an adjacent interference signal, using a BPF (Band-Pass Filter) or the like, and then outputs the IF1 signal. As the intermediate frequency of the IF1 signal, a frequency of 10.7 MHz or 455 kHz is used, for example. The IF1 signal is outputted as an analog signal or a digital signal according to a configuration of the IF amplification unit 6 and subsequent stages.

The IF amplification unit 6 amplifies the IF1 signal by a gain corresponding to the gain control signal G1, to be outputted as the IF1a signal. The demodulation unit 7 demodulates the IF1a signal, to output the AF signal. Moreover, the audio processing unit 8 controls volume and sound quality of the AF signal according to the signal strength signal SDC, to be outputted as the AFa signal. For example, the audio processing unit 8 includes a stereo demodulation unit for demodulating the AF signal into a stereo signal with stereo separation (degree of separation) according to the signal strength signal SDC, and an LPF (Low-Pass Filter) for eliminating from the AF signal a component of a cutoff frequency or more according to the signal strength signal SDC. The speaker 9 converts the AFa signal to sound, to be outputted.

The amplitude level detection unit 111 of the AGC unit 11 detects the amplitude level L1 (hereinafter, referred to as a demodulation unit input level L1) of the IF1a signal to be inputted to the demodulation unit 7 using an envelope detection circuit, for example. The comparison unit 112 compares the demodulation unit input level L1 with the reference level Ref1, to output the comparison result signal CP1 indicating a difference between the two levels. The smoothing processing unit 113 smoothes the comparison result signal CP1 using an integration circuit (LPF), for example, to generate the gain control signal G1.

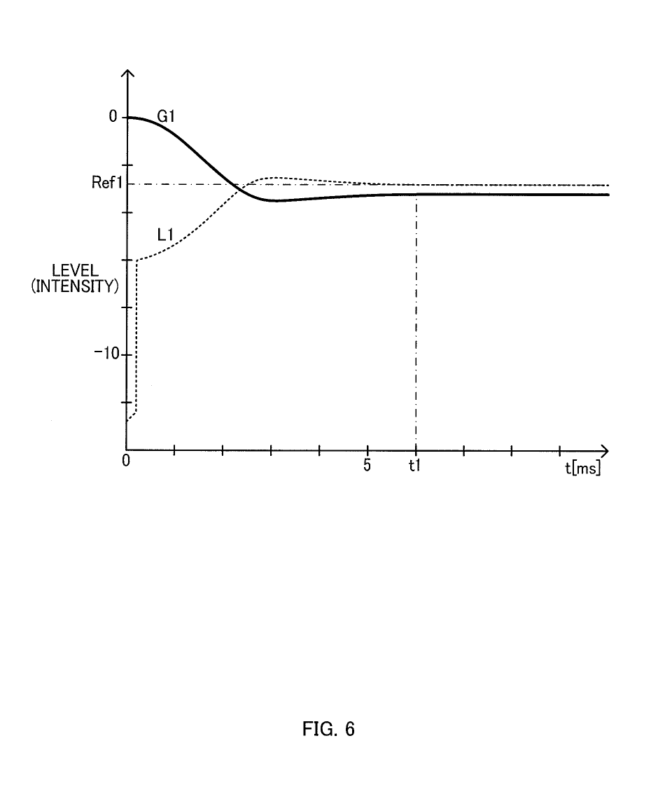

Here, the gain control signal G1 has a waveform, which is inverted as appropriate according to a gain control method in the IF amplification unit 6, however, in the following description, it is assumed as an example that the IF amplification unit 6 includes a fixed gain amplifier and a variable attenuator, and the higher the level of the gain control signal G1 is, the greater an attenuation amount of the variable attenuator becomes (the smaller the gain of the IF amplification unit 6 becomes). In this case, the comparison result signal CP1 has a level of L1-Ref1, and a relationship between the demodulation unit input level L1 and the gain control signal G1 is as illustrated in FIG. 6.

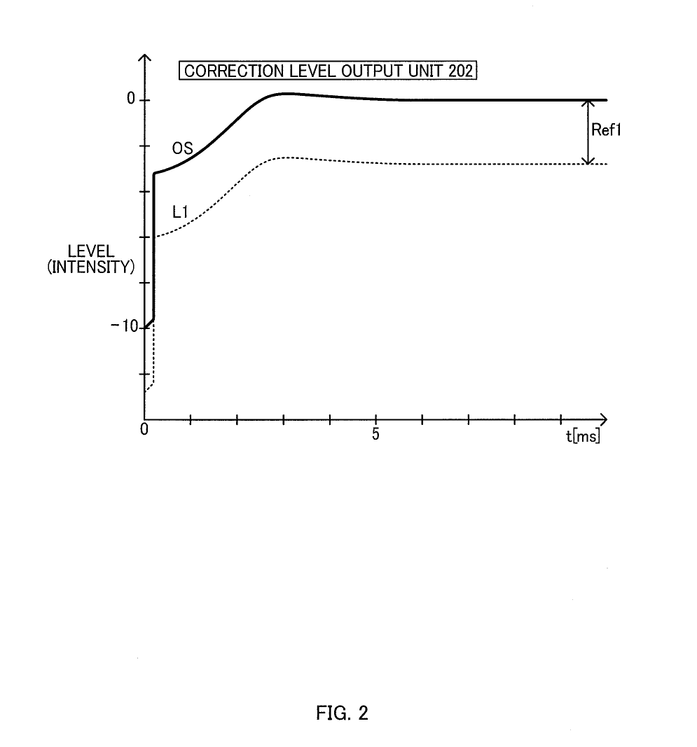

The correction level output unit 202 of the signal strength detection unit 20a outputs a correction level signal OS corresponding to a difference between the demodulation unit input level L1 detected by the amplitude level detection unit 111 and the reference level Ref1 inputted to the comparison unit 112. Here, there is illustrated in FIG. 2 an example of the relationship between the demodulation unit input level L1 and the correction level signal OS. As illustrated in FIG. 2, the correction level signal OS (solid line) has such a waveform as to be displaced from the demodulation unit input level L1 (short broken line) by the reference level Ref1. As in the case of FIG. 6, the reference level Ref1 is a negative level in FIG. 2.

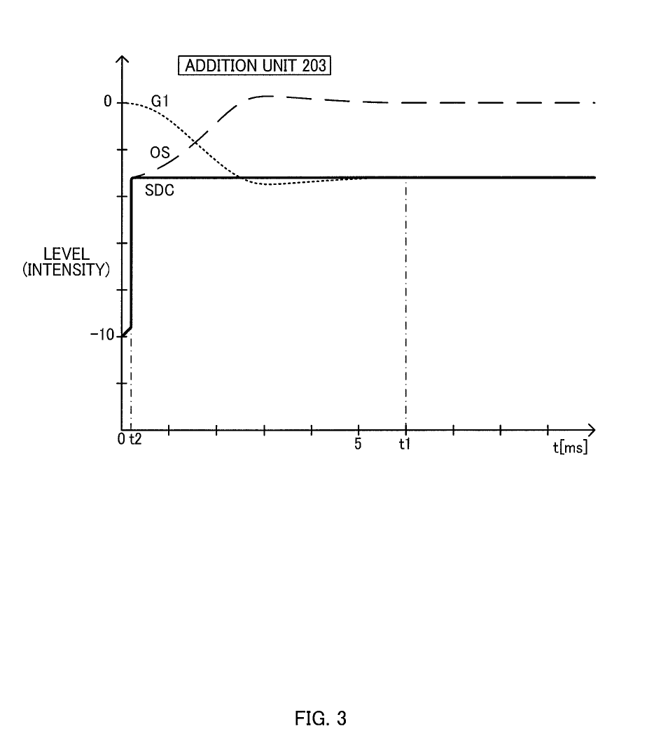

The addition unit 203 adds the gain control signal G1 and the correction level signal OS, to output the signal strength signal SDC. Here, there is illustrated in FIG. 3 an example of the relationship between the input signal and the output signal in the addition unit 203. As illustrated in FIG. 3, the correction level signal OS (long broken line) is added to the gain control signal G1 (short broken line), so that the signal strength signal SDC (solid line) becomes stable at the time of t=t2(<t1).

As such, a signal obtained by adding the correction level signal OS to the gain control signal G1 is used as the signal strength signal SDC indicating the received signal strength of the RF signal in the antenna 1, and thus, a time required for the signal strength signal SDC to become stable can be reduced, as compared with a case where the gain control signal G1 is used as it is.

### Second Embodiment

### Configuration of Receiving Apparatus

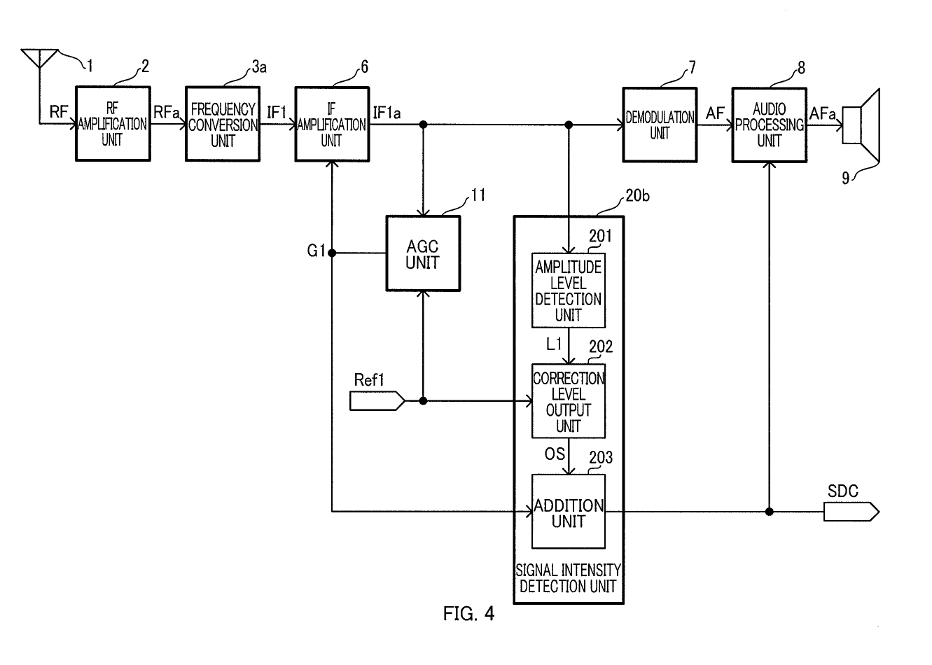

There will hereinafter be described a configuration of a receiving apparatus including a signal strength detection unit according to a second embodiment of the present invention, referring to FIG. 4.

The receiving apparatus illustrated in FIG. 4 includes a signal strength detection unit 20b in place of the signal strength detection unit 20a in the receiving apparatus according to a first embodiment of the present invention.

The signal strength detection unit 20b includes an amplitude level detection unit 201, a correction level output unit 202, and an addition unit 203, for example. The IF1a signal is inputted to the amplitude level detection unit 201, while an output level L1 of the amplitude level detection unit 201 and the reference level Ref1 are inputted to the correction level output unit 202. The correction level signal OS outputted from the correction level output unit 202 and the gain control signal G1 are inputted to the addition unit 203. The signal strength signal SDC outputted from the addition unit 203 is inputted to the audio processing unit 8, for example.

### ===Operation of Receiving Apparatus===

Subsequently, there will be described an operation of the receiving apparatus according to an embodiment of the present invention.

The amplitude level detection unit 201 of the signal strength detection unit 20b detects the demodulation unit input level L1 as in the case of the amplitude level detection unit 111 illustrated in FIG. 1. The correction level output unit 202 outputs the correction level signal OS corresponding to a difference between the demodulation unit input level L1 detected by the amplitude level detection unit 201 and the reference level Ref1 inputted to the AGC unit 11. Moreover, the addition unit 203 adds the gain control signal G1 and the correction level signal OS, to output the signal strength signal SDC.

As is obvious from the above, in the receiving apparatus according to a first embodiment of the present invention, the demodulation unit input level L1 detected in the AGC unit 11 is inputted to the signal strength detection unit 20a, while in the receiving apparatus according to an embodiment of the present invention, the demodulation unit input level L1 is detected in the signal strength detection unit 20b. Therefore, the receiving apparatus according to an embodiment of the present invention can be applied even to a case where the AGC unit 11 does not have a function of outputting the demodulation unit input level L1. In the receiving apparatus according to a first embodiment of the present invention, it is not required that the signal strength detection unit is provided with an amplitude level detection unit independently, and thus, a circuit scale can be reduced.

### Third Embodiment

### Configuration of Receiving Apparatus

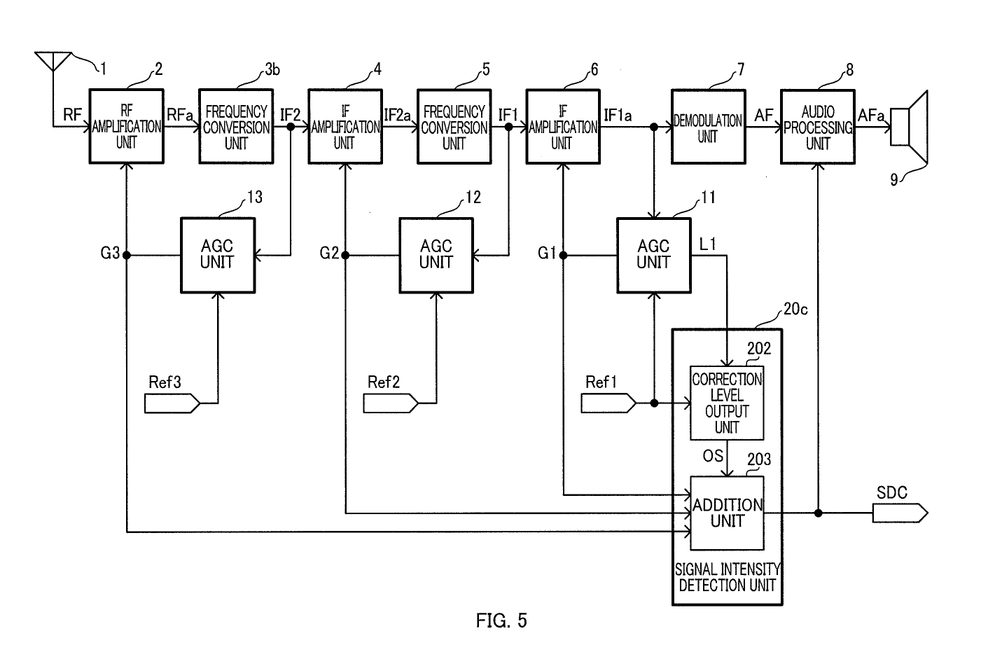

There will hereinafter be described a configuration of a receiving apparatus including a signal strength detection unit according to a third embodiment of the present invention, referring to FIG. 5.

The receiving apparatus illustrated in FIG. 5 is configured as a double superheterodyne receiving apparatus, which includes the antenna 1, the RF amplification unit 2, frequency conversion units 3b and 5, the IF amplification units 4 and 6, the demodulation unit 7, the audio processing unit 8, the speaker 9, the AGC units 11 to 13, and a signal strength detection unit 20c.

The RF signal outputted from the antenna 1 is inputted to the RF amplification unit 2, and the RFa signal outputted from the RF amplification unit 2 is inputted to the frequency conversion unit 3b. An IF2 signal outputted from the frequency conversion unit 3b is inputted to the IF amplification unit 4 and the AGC unit 13, and an IF2a signal outputted from the IF amplification unit 4 is inputted to the frequency conversion unit 5. On the other hand, a gain control signal G3 outputted from the AGC unit 13 is inputted to the RF amplification unit 2 and the signal strength detection unit 20c.

Moreover, the IF1 signal outputted from the frequency conversion unit 5 is inputted to the IF amplification unit 6 and the AGC unit 12, and the IF1a signal outputted from the IF amplification unit 6 is inputted to the demodulation unit 7 and the AGC unit 11. On the other hand, a gain control signal G2 outputted from the AGC unit 12 is inputted to the IF amplification unit 4 and the signal strength detection unit 20c, and the gain control signal G1 outputted from the AGC unit 11 is inputted to the IF amplification unit 6 and the signal strength detection unit 20c.

The AF signal outputted from the demodulation unit 7 is inputted to the audio processing unit 8 and the AFa signal outputted from the audio processing unit 8 is inputted to the speaker 9.

The signal strength detection unit 20c includes the correction level output unit 202 and the addition unit 203, for example. As is the case with the signal strength detection unit 20a according to a first embodiment of the present invention, the demodulation unit input level L1 and the reference level

Ref1 are inputted to the correction level output unit 202. The correction level signal OS outputted from the correction level output unit 202 and the gain control signals G1 to G3 are inputted to the addition unit 203. Then, the signal strength signal SDC outputted from the addition unit 203 is inputted to the audio processing unit 8, for example.

### ===Operation of Receiving Apparatus===

Subsequently, there will be described an operation of the receiving apparatus according to an embodiment of the present invention.

The antenna 1 outputs the RF signal as in the case of the receiving apparatus according to a first embodiment of the present invention, and the RF amplification unit 2 selectively amplifies a frequency band including a desired carrier wave in the RF signal by a gain corresponding to the gain control signal

G3, to be outputted as the RFa signal. The frequency conversion unit 3b frequency-converts the RFa signal, rejects an interference signal, as appropriate, such as an image signal or an adjacent interference signal using the BPF or the like, and then outputs the IF2 signal. Moreover, the IF amplification unit 4 amplifies the IF2 signal by a gain corresponding to the gain control signal G2, to be outputted as the IF2a signal. The frequency conversion unit 5 further frequency-converts the IF2a signal, to output the IF1 signal. The (intermediate) frequency of the IF2 signal is set at a frequency at least higher than the intermediate frequency of the IF1 signal. Particularly, in order to reliably reject the image signal, the frequency may be set at a frequency higher than the radio frequency of the RF signal.

The IF amplification unit 6 amplifies the IF1 signal by a gain corresponding to the gain control signal G1, to be outputted as the IF1a signal. The demodulation unit 7 demodulates the IF1a signal, to output the AF signal. Moreover, the audio processing unit 8 controls volume and sound quality of the AF signal according to the signal strength signal SDC, to be outputted as the AFa signal. Then, the speaker 9 converts the AFa signal to sound, to be outputted.

The AGC unit 13 has a configuration similar to that of the AGC unit 11 illustrated in FIG. 1, for example, and smoothes a difference between the amplitude level of the IF2 signal and a reference level Ref3, to generate the gain control signal G3. Similarly, the AGC unit 12 smoothes a difference between the amplitude level of the IF1 signal and the reference level Ref2, to generate the gain control signal G2. Moreover, similarly, the AGC unit 11 smoothes a difference between the amplitude level (demodulation unit input level L1) of the IF1a signal and the reference level Ref1, to generate the gain control signal G1.

Here, the gain control signals G1 to G3 have waveforms, which are inverted as appropriate according to gain control methods in the RF amplification unit 2 and the IF amplification units 4 and 6, however, in the following description, it is assumed as an example that the higher the levels of the gain control signals are, the smaller the gains of the respectively corresponding amplification units become. Moreover, it is assumed that the relationships between the levels of the gain control signals and the gains of the amplification units are substantially equivalent. In this case, the sum of the levels of the gain control signals indicates the total gain of the amplification units, and the sum of the three gain control signals G1 to G3 in the receiving apparatus according to an embodiment of the present invention can be considered as with the single gain control signal G1 in the receiving apparatus according to a first embodiment of the present invention. Even if the relationship between the levels of the gain control signals and the gains of the amplification units is different from the above, the gain control signals are multiplied by an positive or negative coefficient as appropriate, to be inputted to the signal strength detection unit 20c, so that the sum of the levels of the gain control signals indicates the total gain of the amplification units, and the sum of the three gain control signals G1 to G3 in the receiving apparatus according to an embodiment of the present invention can be considered as with the single gain control signal G1 in the receiving apparatus according to a first embodiment of the present invention.

As is the case with the signal strength detection unit 20a according to a first embodiment of the present invention, the correction level output unit 202 of the signal strength detection unit 20c outputs the correction level signal OS corresponding to a difference between the demodulation unit input level L1 detected in the AGC unit 11 and the reference level Ref1 inputted to the AGC unit 11. The addition unit 203 adds the sum of the gain control signals G1 to G3 and the correction level signal OS, to output the signal strength signal SDC.

As such, in the receiving apparatus according to an embodiment of the present invention including a plurality of the AGC units, a signal obtained by adding the correction level signal OS to the sum of the gain control signals G1 to G3 is used as the signal strength signal SDC indicating the received signal strength of the RF signal in the antenna 1, and thus, the time required for the signal strength signal SDC to become stable can be reduced, as compared with a case where the sum of the gain control signals G1 to G3 is used as it is.

As mentioned above, as the signal strength signal SDC indicating the received signal strength of the RF signal in the antenna 1, a signal obtained by adding to the gain control signal G1 the correction level signal OS corresponding to a difference between the demodulation unit input level L1 and the reference level Ref1 is used, so that the time required for the signal strength signal SDC to become stable can be reduced, as compared with the case where the gain control signal G1 is used as it is.

Moreover, the demodulation unit input level L1 is inputted to the correction level output unit 202 from the amplitude level detection unit 111 of the AGC unit 11, and thus, it is not required that the signal strength detection unit is provided with the amplitude level detection unit independently, so that the circuit scale can be reduced.

Furthermore, even if the receiving apparatus includes the plurality of AGC units, since a signal obtained by adding the correction level signal OS to the sum of the gain control signals G1 to G3 is used as the signal strength signal SDC, the time required for the signal strength signal SDC to become stable can be reduced, as compared with the case where the sum of the gain control signals G1 to G3 is used as it is.

Furthermore, even if the receiving apparatus includes the plurality of AGC units, since the demodulation unit input level L1 is inputted to the correction level output unit 202 from the AGC unit 11, which allows the IF1a signal to be inputted thereto as well as the demodulation unit 7, it is not required that the signal strength detection unit is provided with the amplitude level detection unit independently, and thus, the circuit scale can be reduced.

Furthermore, the audio processing unit 8 demodulates the AF signal into a stereo signal with stereo separation according to the signal strength signal SDC, and thus, specific noise of the stereo signal in a state of a weak electric field with low received signal strength can be reduced.

Furthermore, since the audio processing unit 8 eliminates from the AF signal a component at the cutoff frequency or more according to the signal strength signal SDC, the noise of a high frequency in the sate of the weak electric field can be suppressed and the ratio of an effective signal to noise can be improved.

In embodiments of the present invention described above, the receiving apparatus is configured as a (single) superheterodyne receiving apparatus including a single AGC unit or a double superheterodyne receiving apparatus including three AGC units, however, this is not limitative. The receiving apparatus is only required to include one or more AGC units in a stage prior to the demodulation unit 7, and the number of AGC units and the number of stages of intermediate frequency conversion is not limited.

In embodiments of the present invention described above, the receiving apparatus controls volume and sound quality of the AF signal according to the signal strength signal SDC in the audio processing unit 8, however, this is not limitative. The receiving apparatus may include a detection unit for detecting other reception statuses such as presence or absence of an adjacent interference signal or a multipass interference signal. Furthermore, each amplification unit may include a filter such as a BPF whose passband is changed according to a combination of these reception statuses.

The above embodiments of the present invention are simply for facilitating the understanding of the present invention and are not in any way to be construed as limiting the present invention. The present invention may variously be changed or altered without departing from its spirit and encompass equivalents thereof.

What is claimed is:

1. A receiving apparatus comprising:
a frequency conversion unit configured to convert a received radio frequency signal to an intermediate frequency signal;
an automatic gain control unit configured to control an amplitude level of at least either one of the radio frequency signal and the intermediate frequency signal according to a gain control signal;
a demodulation unit configured to demodulate an audio signal from the intermediate frequency signal;
a correction level output unit configured to output a correction level signal corresponding to a difference between a demodulation unit input level and a predetermined reference level, the demodulation unit input level being an amplitude level of the intermediate frequency signal inputted to the demodulation unit; and
an addition unit configured to add the gain control signal and the correction level signal, to be outputted as a signal strength signal indicating received signal strength of the radio frequency signal.

2. The receiving apparatus according to claim 1, wherein
the automatic gain control unit includes:
an amplitude level detection unit configured to detect the demodulation unit input level; and
a smoothing processing unit configured to smooth a difference between the demodulation unit input level and the predetermined reference level, to generate the gain control signal.

3. The receiving apparatus according to claim 1, further comprising
a plurality of automatic gain control units as the automatic gain control unit, wherein
the addition unit adds the sum of the respective gain control signals of the automatic gain control units and the correction level signal, to output the signal strength signal.

4. The receiving apparatus according to claim 3, wherein
at least one of the automatic gain control units includes:
an amplitude level detection unit configured to detect the demodulation unit input level; and
a smoothing processing unit configured to smooth a difference between the demodulation unit input level and the predetermined reference level, to generate the gain control signal.

5. The receiving apparatus according to claim 1 further comprising
an audio processing unit configured to control a degree of separation of a stereo audio signal according to the signal strength signal, and wherein
the audio signal includes the stereo audio signal.

6. The receiving apparatus according to claim 2 further comprising
an audio processing unit configured to control a degree of separation of a stereo audio signal according to the signal strength signal, and wherein
the audio signal includes the stereo audio signal.

7. The receiving apparatus according to claim 3 further comprising
an audio processing unit configured to control a degree of separation of a stereo audio signal according to the signal strength signal, and wherein
the audio signal includes the stereo audio signal.

8. The receiving apparatus according to claim 4 further comprising
an audio processing unit configured to control a degree of separation of a stereo audio signal according to the signal strength signal, and wherein
the audio signal includes the stereo audio signal.

9. The receiving apparatus according to claim 1, further comprising
an audio processing unit configured to remove a component at a predetermined frequency or more included in the audio signal according to the signal strength signal.

10. The receiving apparatus according to claim 2, further comprising
an audio processing unit configured to remove a component at a predetermined frequency or more included in the audio signal according to the signal strength signal.

11. The receiving apparatus according to claim 3, further comprising
an audio processing unit configured to remove a component at a predetermined frequency or more included in the audio signal according to the signal strength signal.

12. The receiving apparatus according to claim 4, further comprising
an audio processing unit configured to remove a component at a predetermined frequency or more included in the audio signal according to the signal strength signal.
